(19) United States
(12) Patent Application Publication
(10) Pub. No.: US 2025/0239977 A1
(43) Pub. Date: Jul. 24, 2025

(54) LOADLINE MODULATION POWER MANAGEMENT CIRCUIT

(71) Applicant: Qorvo US, Inc., Greensboro, NC (US)

(72) Inventor: Nadim Khlat, Cugnaux (FR)

(21) Appl. No.: 18/970,022

(22) Filed: Dec. 5, 2024

Related U.S. Application Data
(60) Provisional application No. 63/622,603, filed on Jan. 19, 2024.
(60) Provisional application No. 63/638,469, filed on Apr. 25, 2024.

(51) Int. Cl. H03F 3/24; H03F 1/56; H03F 3/45; H03H 7/075; H04B 1/04

(52) U.S. Cl. CPC H03F 3/24; H03F 1/565; H03F 3/45475; H03H 7/075; H04B 1/0475; H03F 2200/102; H04B 2001/0408

(57) ABSTRACT

A loadline modulation power management circuit is provided. The loadline modulation power management circuit includes a power amplifier circuit and an acoustic filter circuit. Specifically, the power amplifier circuit is configured to amplify a signal to a time-variant output power based on a modulated voltage and the acoustic filter circuit is configured to pass the amplified signal for transmission in a transmit frequency. Herein, the power amplifier circuit is further configured to dynamically modulate a loadline impedance based on the time-variant output power to prevent the modulated voltage from exceeding a maximum level, whereas the acoustic filter circuit can help reduce overall transmit loss in the amplified signal. As a result, the loadline modulation power management circuit can operate with optimal efficiency and with reduced overall transmit loss.

### RELATED APPLICATIONS

This application claims the benefit of U.S. provisional patent application Ser. No. 63/622,603, filed on Jan. 19, 2024, and U.S. provisional patent application Ser. No. 63/638,469, filed on Apr. 25, 2024, the disclosures of which are hereby incorporated herein by reference in their entireties.

### FIELD OF THE DISCLOSURE

The technology of the disclosure relates generally to a power management circuit.

### BACKGROUND

The fifth generation (5G) system has been widely regarded as the next generation of wireless communication systems beyond the current third generation (3G) and fourth generation (4G) systems. In this regard, a 5G-capable wireless communication device is expected to achieve higher data rates, improved coverage range, enhanced signaling efficiency, and reduced latency.

The 5G-capable wireless communication device typically includes multiple transmitters to simultaneously transmit multiple 5G radio frequency (RF) signals under such schemes as Carrier Aggregation (CA) and Evolved-Universal Terrestrial Radio Access (E-UTRA) New Radio (NR) Dual Connectivity (DC) (ENDC). Since the transmitters typically transmit the 5G RF signals in a millimeter wave spectrum, the RF signals can be more susceptible to propagation attenuation and interference. To help mitigate propagation attenuation and maintain desirable data throughput, the 5G-capable wireless communication device typically employs multiple power amplifiers to amplify the RF signals to desired power levels before transmitting the RF signals from the transmitters. As such, it is desirable to ensure that the power amplifiers can operate with optimal efficiency, especially when the RF signals are transmitted with large peak-to-average ratios (PARs).

### SUMMARY

Embodiments of the disclosure relate to a loadline modulation power management circuit. The loadline modulation power management circuit includes a power amplifier circuit and an acoustic filter circuit. Specifically, the power amplifier circuit is configured to amplify a signal to a time-variant output power based on a modulated voltage and the acoustic filter circuit is configured to pass the amplified signal for transmission in a transmit frequency. Herein, the power amplifier circuit is further configured to dynamically modulate a loadline impedance based on the time-variant output power to prevent the modulated voltage from exceeding a maximum level, whereas the acoustic filter circuit can help reduce overall transmit loss in the amplified signal. As a result, the loadline modulation power management circuit can operate with optimal efficiency and with reduced overall transmit loss.

In one aspect, a loadline modulation power management circuit is provided. The loadline modulation power management circuit includes a power amplifier circuit. The power amplifier circuit includes a differential amplifier. The differential amplifier is always activated. The differential amplifier is configured to receive an envelope tracking (ET) voltage having a dynamic range defined by a minimum voltage level and a maximum voltage level. The differential amplifier is also configured to amplify a signal from a time-variant input power to a time-variant output power that is inversely related to a default loadline impedance based on the ET voltage. The power amplifier circuit also includes a single-ended amplifier. The single-ended amplifier is activated when the time-variant output power is higher than or equal to a threshold level to reduce the default loadline impedance to thereby prevent the ET voltage from exceeding the maximum voltage level when the time-variant output power of the signal is higher than the threshold level. The loadline modulation power management circuit also includes an acoustic filter circuit. The acoustic filter circuit includes an acoustic impedance inverter circuit and an acoustic network circuit. The acoustic filter circuit is configured to pass the amplified signal in a transmit frequency and reject the signal outside the transmit frequency.

In another aspect, a wireless device is provided. The wireless device includes a loadline modulation power management circuit. The loadline modulation power management circuit includes a power amplifier circuit. The power amplifier circuit includes a differential amplifier. The differential amplifier is always activated. The differential amplifier is configured to receive an ET voltage having a dynamic range defined by a minimum voltage level and a maximum voltage level. The differential amplifier is also configured to amplify a signal from a time-variant input power to a time-variant output power that is inversely related to a default loadline impedance based on the ET voltage. The power amplifier circuit also includes a single-ended amplifier. The single-ended amplifier is activated when the time-variant output power is higher than or equal to a threshold level to reduce the default loadline impedance to thereby prevent the ET voltage from exceeding the maximum voltage level when the time-variant output power of the signal is higher than the threshold level. The loadline modulation power management circuit also includes an acoustic filter circuit. The acoustic filter circuit includes an acoustic impedance inverter circuit and an acoustic network circuit. The acoustic filter circuit is configured to pass the amplified signal in a transmit frequency and reject the signal outside the transmit frequency.

In another aspect, a method for performing loadline modulation is provided. The method includes receiving, by a differential amplifier that is always activated, an ET voltage having a dynamic range defined by a minimum voltage level and a maximum voltage level. The method also includes amplifying, by the differential amplifier, a signal from a time-variant input power to a time-variant output power that is inversely related to a default loadline impedance based on the ET voltage. The method also includes activating a single-ended amplifier when the time-variant output power is higher than or equal to a threshold level to reduce the default loadline impedance to thereby prevent the ET voltage from exceeding the maximum voltage level when the time-variant output power of the signal is higher than the threshold level. The method also includes passing the amplified signal in a transmit frequency and rejecting the signal outside the transmit frequency.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary loadline modulation power management circuit wherein a power amplifier circuit is configured to perform loadline modulation and an acoustic filter circuit is configured to reduce transmit loss;

FIG. 2 is a graphic diagram providing an exemplary illustration of the loadline modulation being performed by the loadline modulation power management circuit of claim 1;

FIGS. 3A-3D are schematic diagrams illustrating various embodiments of the acoustic filter circuit in FIG. 1;

FIG. 4 is a schematic diagram of an exemplary communication device wherein the loadline modulation power management circuit of FIG. 1 can be provided; and

FIG. 5 is a flowchart of an exemplary process whereby the loadline modulation power management circuit of FIG. 1 can be configured to perform the loadline modulation.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a loadline modulation power management circuit. The loadline modulation power management circuit includes a power amplifier circuit and an acoustic filter circuit. Specifically, the power amplifier circuit is configured to amplify a signal to a time-variant output power based on a modulated voltage and the acoustic filter circuit is configured to pass the amplified signal for transmission in a transmit frequency. Herein, the power amplifier circuit is further configured to dynamically modulate a loadline impedance based on the time-variant output power to prevent the modulated voltage from exceeding a maximum level, whereas the acoustic filter circuit can help reduce overall transmit loss in the amplified signal. As a result, the loadline modulation power management circuit can operate with optimal efficiency and with reduced overall transmit loss.

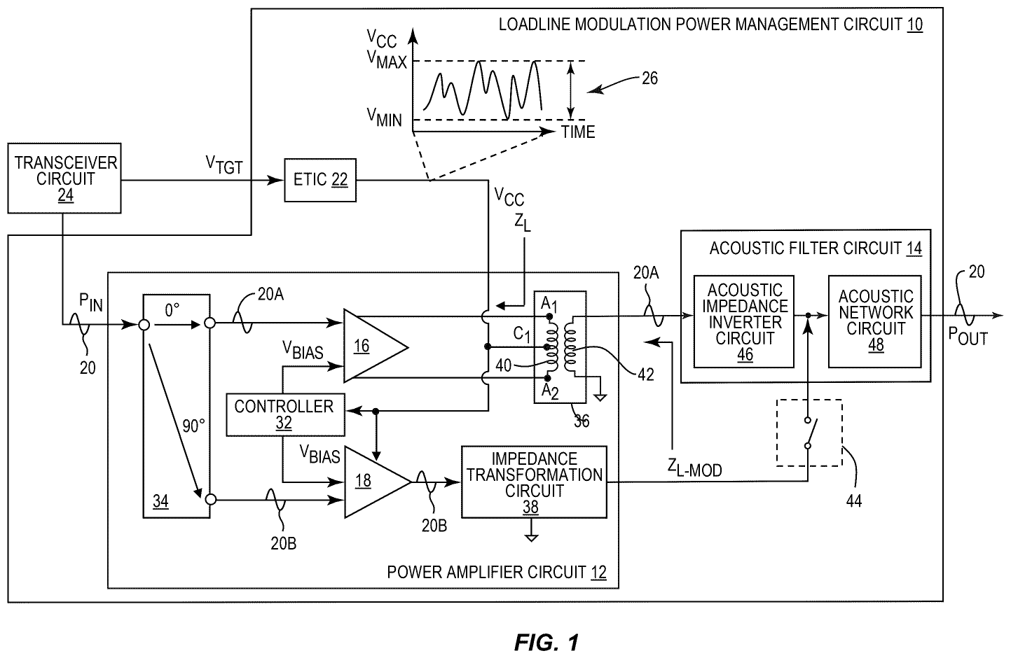

FIG. 1 is a schematic diagram of an exemplary loadline modulation power management circuit 10 wherein a power amplifier circuit 12 is configured to perform loadline modulation and an acoustic filter circuit 14 is configured to reduce transmit loss. The power amplifier circuit 12 includes a differential amplifier 16 and a single-ended amplifier 18. In context of the present disclosure, the single-ended amplifier 18 can be any amplifier except a differential amplifier.

Herein, the differential amplifier 16 is always active to amplify a signal 20 from a time-variant input power P_{IN} to a time-variant output power P_{OUT} based on an envelope tracking (ET) voltage V_{CC}. In an embodiment, the ET voltage V_{CC} is generated by an ET integrated circuit (ETIC) 22 in accordance with an ET target voltage V_{TGT} that is provided by a transceiver circuit 24. Since the transceiver circuit 24 also generates the signal 20 in the time-variant input power P_{IN}, the transceiver circuit 24 can thus generate the ET target voltage V_{TGT} in accordance with the time-input power P_{IN}. Accordingly, the ETIC 22 can generate the ET voltage V_{CC} to closely track the time-variant input power P_{IN}. Specifically, the ET voltage V_{CC} is confined within a dynamic range 26 as defined by a minimum voltage level V_{MIN} (e.g., 0.8 V) and a maximum voltage level V_{MAX} (e.g., 5.5 V).

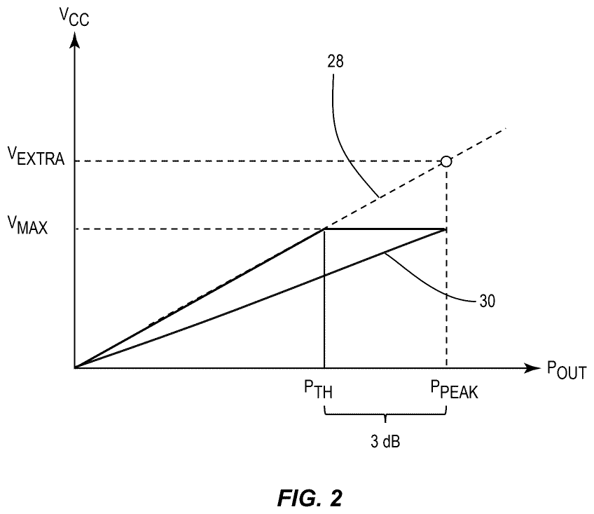

The differential amplifier 16 is typically configured to operate according to a default loadline impedance Z_{L} for better efficiency. FIG. 2 is a graphic diagram providing an exemplary illustration of a loadline 28 representing the default loadline impedance Z_{L}.

According to the loadline 28, the time-variant output power P_{OUT} is approximately a function of the ET voltage V_{CC} and the default loadline impedance Z_{L} (P_{OUT}≈V_{CC}²/Z_{L}). As illustrated, the ET voltage V_{CC} (V_{CC}≈\sqrt{P_{OUT}*Z_{L}}) reaches the maximum voltage level V_{MAX} when the time-variant output power P_{OUT} reaches a threshold level P_{TH}. Beyond the threshold level P_{TH}, the ET voltage V_{CC} must continue rising beyond the maximum voltage level V_{MAX} (e.g., V_{EXTRA}) to drive the time-variant output power P_{OUT} to a peak power level P_{PEAK}. This can create a significant impact on the ETIC 22 in terms of current consumption and heat dissipation. As such, it is desirable to prevent the ET voltage V_{CC} from exceeding the maximum voltage level V_{MAX} when the time-variant output power P_{OUT} is at the peak power level P_{PEAK}.

In this regard, the single-ended amplifier 18 is activated to modulate the default loadline impedance Z_{L} when the time-variant output power Pour is higher than or equal to the threshold level P_{TH} (e.g., P_{TH}=P_{PEAK}−3 dB). Herein, the single-ended amplifier 18 can change the default loadline impedance Z_{L} to a modified loadline impedance Z_{L-MOD} (Z_{L-MOD}<Z_{L}). Accordingly, the differential amplifier 16 will operate based on a modified loadline 30, wherein the time-variant output power P_{OUT} is approximately a function of the ET voltage V_{CC} and the modified loadline impedance Z_{L-MOD} (P_{OUT}≈V_{CC}²/Z_{L-MOD}). As illustrated herein, since the modified loadline impedance Z_{L-MOD} is smaller than the default loadline impedance Z_{L}, the ET voltage V_{CC} (V_{CC}≈\sqrt{P_{OUT}*Z_{L-MOD}}) for driving the time-variant output power P_{OUT} to the peak power level P_{PEAK} can become lower.

As a result, it is possible to prevent the ET voltage V_{CC} from exceeding the maximum voltage level V_{MAX} at the peak power level P_{PEAK}. In other words, the ET voltage V_{CC} will stay within the dynamic range 26 when the time-variant output power P_{OUT} is higher than the threshold level P_{TH}.

With reference back to FIG. 1, the power amplifier circuit 12 can include a controller 32, which is configured to provide a bias voltage V_{BIAS} to the differential amplifier 16 and the single-ended amplifier 18. In an embodiment, the controller 32 can be configured to activate the single-ended amplifier 18 when the time-variant output power P_{OUT} reaches the threshold level P_{TH} (P_{OUT}≥P_{TH}) by providing the bias voltage V_{BIAS} to the single-ended amplifier 18 and deactivate the single-ended amplifier 18 when the time-variant output power P_{OUT} drops below the threshold level P_{TH} (P_{OUT}<P_{TH}) by removing the bias voltage V_{BIAS} from the single-ended amplifier 18. As an example, the controller 32 can determine whether to activate or deactivate the single-ended amplifier 18 based on the ET voltage V_{CC}.

The power amplifier circuit 12 can also include a splitter 34 that splits the signal 20 into a pair of signals 20A, 20B, each having one-half of the time-variant input power P_{IN} (½P_{IN}). In an embodiment, the signal 20A is in-phase with the signal 20, whereas the signal 20B has a ninety-degree (90°) degree phase offset relative to the signal 20.

The power amplifier circuit 12 further includes a transformer circuit 36 and an impedance transformation circuit 38. The transformer circuit 36 includes an input coil 40 and an output coil 42. The input coil 40 is coupled to the differential amplifier 16 and the output coil 42 is coupled to the acoustic filter circuit 14. Herein, the modulated voltage V_{CC} is provided to a center node C₁ of the input coil 40, and the default loadline impedance Z_{L} is provided by a pair of outer nodes A₁, A₂ of the input coil 40. The output coil 42 is configured to provide the signal 20A, as amplified by the differential amplifier 16, to the acoustic filter circuit 14.

The impedance transformation circuit 38 is configured to reduce the default loadline impedance Z_{L} to the modified loadline impedance Z_{L-MOD} when the single-ended amplifier 18 is activated. The impedance transformation circuit 38 may be coupled to the acoustic filter circuit 14 via a switch 44. In an embodiment, the switch 44 may be closed when the single-ended amplifier 18 is activated and opened when the single-ended amplifier 18 is deactivated. The acoustic filter circuit 14 can be configured to include an acoustic

impedance inverter circuit 46 and an acoustic network circuit 48. In general, the acoustic filter circuit 14 is configured to pass the amplified signal 20 in a transmit frequency and reject the signal 20 outside the transmit frequency.

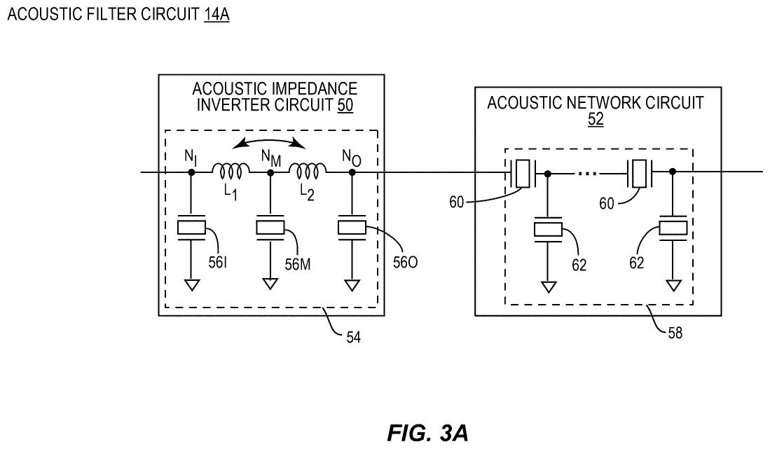

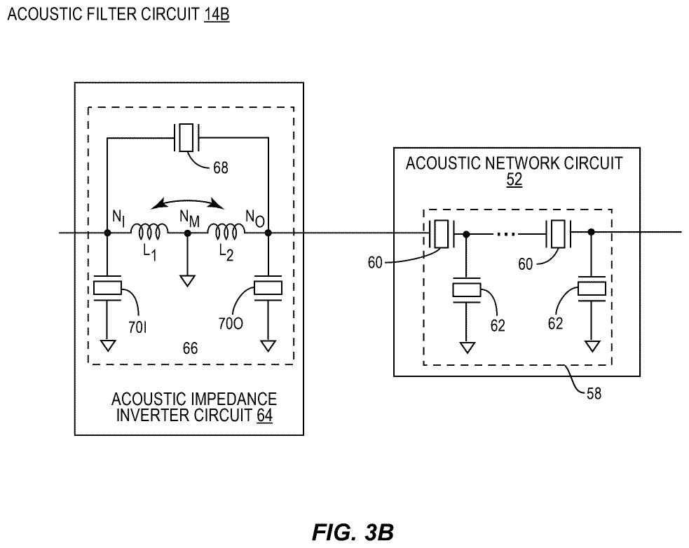

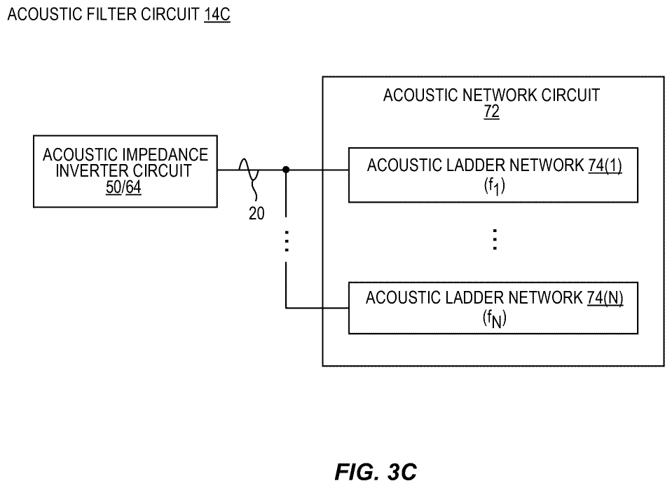

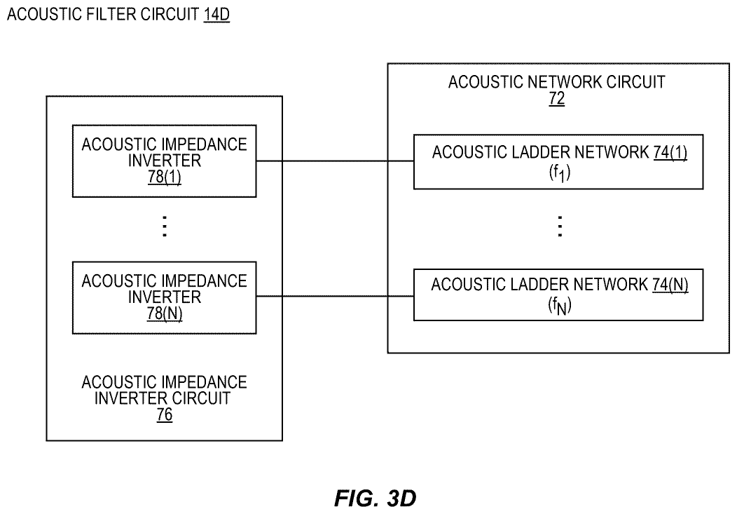

The acoustic filter circuit 14 can be configured according to various embodiments of the present disclosure, as further described below in FIGS. 3A-3D. FIGS. 3A-3D are schematic diagrams illustrating various embodiments of the acoustic filter circuit 14 in FIG. 1. Common elements between FIGS. 1 and 3A-3D are shown therein with common element numbers and will not be re-described herein.

FIG. 3A illustrates an acoustic filter circuit 14A configured according to one embodiment of the present disclosure. Herein, the acoustic filter circuit 14A includes an acoustic impedance inverter circuit 50 and an acoustic network circuit 52. The acoustic impedance inverter circuit 50 includes an acoustic impedance inverter 54 (e.g., a k-inverter). In an embodiment, the acoustic impedance inverter 54 includes a pair of inductors L₁, L₂, an input shunt resonator 56I, an output shunt resonator 56O, and a middle shunt resonator 56M. The pair of inductors L₁, L₂ are coupled in series between an input node N_{I} and an output node N_{O}. The input shunt resonator 56I is coupled between the input node N_{I} and a ground, the output shunt resonator 56O is coupled between the output node N_{O} and the ground, and the middle shunt resonator 56M is coupled between a middle node N_{M} and the ground.

The acoustic network circuit 52, on the other hand, includes an acoustic ladder network 58 that is coupled to the output node N_{O}. In an embodiment, the acoustic ladder network 58 can include one or more respective series resonators 60 and one or more respective shunt resonators 62. FIG. 3B illustrates an acoustic filter circuit 14B configured according

to another embodiment of the present disclosure. Herein, the acoustic filter circuit 14B includes an acoustic impedance inverter circuit 64 that includes an acoustic impedance inverter 66. The acoustic impedance inverter 66 includes a parallel acoustic resonator 68, an input shunt resonator 70I, and an output shunt resonator 70O. The parallel acoustic resonator 68 is coupled between the input node N_{I} and the output node N_{O} in parallel to the pair of inductors L₁, L₂. The input shunt resonator 70I is coupled between the input node N_{I} and the ground, the output shunt resonator 70O is coupled between the output node N_{O} and the ground, whereas the middle node N_{M} is coupled directly to the ground. FIG. 3C illustrates an acoustic filter circuit 14C configured according

to another embodiment of the present disclosure. Herein, the acoustic filter circuit 14C can include an acoustic network circuit 72 that includes multiple acoustic ladder networks 74(1)-74(N). In an embodiment, each of the acoustic ladder networks 74(1)-74(N) is identical or functionally equivalent to the acoustic ladder network 58 in FIGS. 3A and 3B. Each of the acoustic ladder networks 74(1)-74(N) is configured to pass the signal 20 in a respective one of multiple transmit frequencies f₁-f_{N}.

FIG. 3D illustrates an acoustic filter circuit 14D configured according to another embodiment of the present disclosure. Herein, the acoustic filter circuit 14D can include an acoustic impedance inverter circuit 76. The acoustic impedance inverter circuit 76 includes multiple acoustic impedance inverters 78(1)-78(N). Herein, each of the acoustic impedance inverters 78(1)-78(N) can be configured according to a respective frequency band (e.g., among multiple different transmit frequency bands). In an embodiment, each of the acoustic impedance inverters 78(1)-78(N) can be identical or functionally equivalent to any of the acoustic impedance inverter 54 in FIG. 3A and the acoustic impedance inverter 66 in FIG. 3B. The acoustic impedance inverters 78(1)-78(N) are coupled to the acoustic ladder networks 74(1)-74(N), respectively.

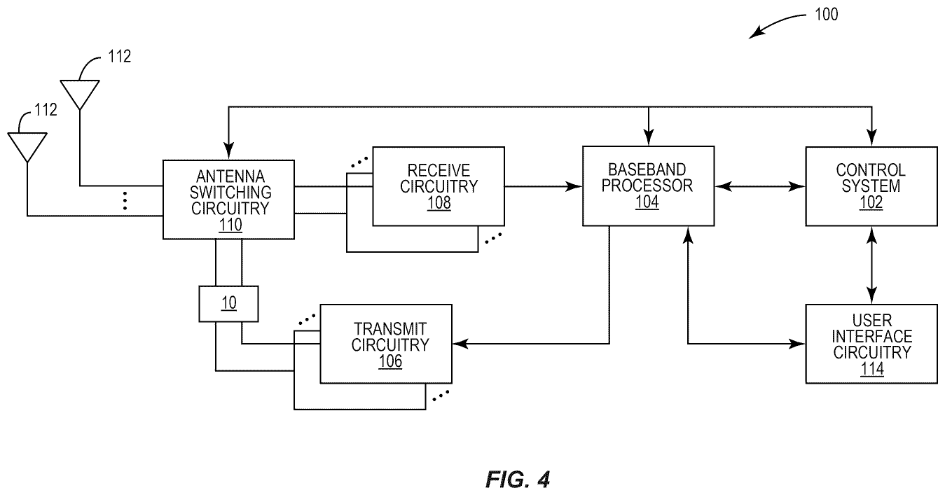

The loadline modulation power management circuit 10 of FIG. 1 can be provided in a communication device to enable the embodiments described above. In this regard, FIG. 4 is a schematic diagram of an exemplary communication device 100 wherein the loadline modulation power management circuit 10 of FIG. 1 can be provided.

Herein, the communication device 100 can be any type of communication device, such as mobile terminal, smart watch, tablet, computer, navigation device, access point, base station (e.g., eNB, gNB, etc.), and like wireless communication devices that support wireless communications, such as cellular, wireless local area network (WLAN), Bluetooth, Ultra-wideband (UWB), and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

In an embodiment, the loadline modulation power management circuit 10 may be provided between the transmit circuitry 106 and the antenna switching circuitry 110. Accordingly, the transmit circuitry 106 can be configured to function as the transceiver circuit 24 in FIG. 1.

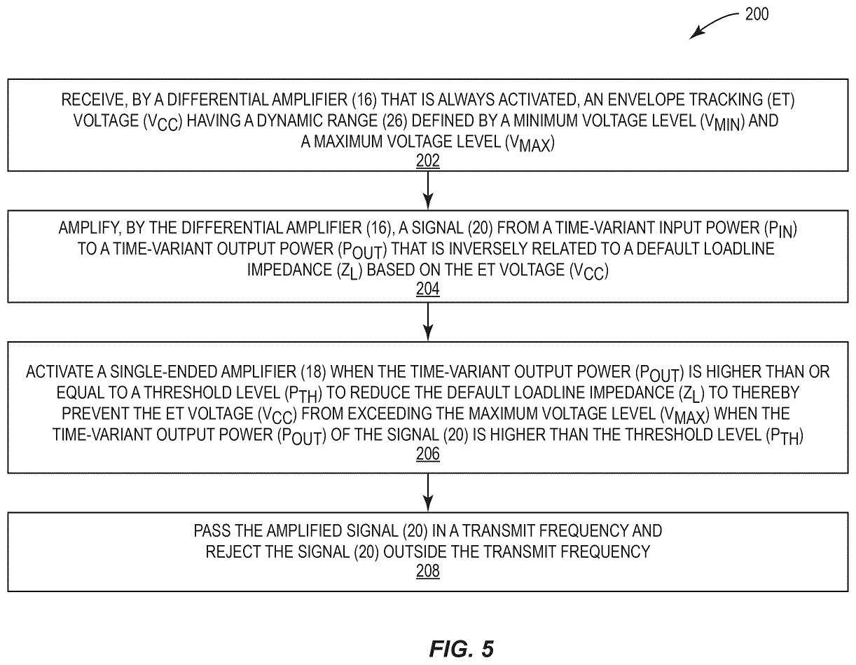

In an embodiment, the loadline modulation power management circuit 10 of FIG. 1 can be configured to perform loadline modulation according to a process. In this regard, FIG. 5 is a flowchart of an exemplary process 200 whereby the loadline modulation power management circuit 10 of FIG. 1 can be configured to perform the loadline modulation.

Herein, the process 200 includes receiving, by the differential amplifier 16 that is always activated, the ET voltage V_{CC} having the dynamic range 26 defined by the minimum voltage level V_{MIN} and the maximum voltage level V_{MAX} (step 202). The process 200 also includes amplifying, by the differential amplifier 16, the signal 20 from the time-variant input power P_{IN} to the time-variant output power P_{OUT} that is inversely related to the default loadline impedance Z_{L} based on the ET voltage V_{CC} (step 204). The process 200 also includes activating the single-ended amplifier 18 when the time-variant output power P_{OUT} is higher than or equal to the threshold level P_{TH} to reduce the default loadline impedance Z_{L} to thereby prevent the ET voltage V_{CC} from exceeding the maximum voltage level V_{MAX} when the time-variant output power P_{OUT} of the signal 20 is higher than the threshold level P_{TH} (step 206). The process 200 also includes passing the amplified signal 20 in the transmit frequency and rejecting the signal 20 outside the transmit frequency (step 208).

Those skilled in the art will recognize improvements and modifications to the preferred embodiments of the present disclosure. All such improvements and modifications are considered within the scope of the concepts disclosed herein and the claims that follow.

What is claimed is:

1. A loadline modulation power management circuit comprising:
a power amplifier circuit, comprising:
a differential amplifier always activated and configured to:
receive an envelope tracking (ET) voltage having a dynamic range defined by a minimum voltage level and a maximum voltage level; and
amplify a signal from a time-variant input power to a time-variant output power that is inversely related to a default loadline impedance based on the ET voltage; and
a single-ended amplifier activated when the time-variant output power is higher than or equal to a threshold level to reduce the default loadline impedance to thereby prevent the ET voltage from exceeding the maximum voltage level when the time-variant output power of the signal is higher than the threshold level; and
an acoustic filter circuit comprising an acoustic impedance inverter circuit and an acoustic network circuit and configured to pass the amplified signal in a transmit frequency and reject the signal outside the transmit frequency.

2. The loadline modulation power management circuit of claim 1, wherein the single-ended amplifier is deactivated when the time-variant output power is lower than the threshold level.

3. The loadline modulation power management circuit of claim 1, further comprising:
a transformer circuit configured to couple the differential amplifier to an input of the acoustic impedance inverter circuit; and
an impedance transformation circuit coupled between the single-ended amplifier and an output of the acoustic impedance inverter circuit and configured to reduce the default loadline impedance when the single-ended amplifier is activated.

4. The loadline modulation power management circuit of claim 1, wherein:
the acoustic impedance inverter circuit comprises an acoustic impedance inverter comprising:
a pair of inductors coupled in series between an input node and an output node;
an input shunt resonator coupled between the input node and a ground;
an output shunt resonator coupled between the output node and the ground; and
a middle shunt resonator coupled between a middle node and the ground; and
the acoustic network circuit comprises an acoustic ladder network coupled to the output node.

5. The loadline modulation power management circuit of claim 1, wherein:
the acoustic impedance inverter circuit comprises an acoustic impedance inverter comprising:
a pair of inductors coupled in series between an input node and an output node;
a parallel acoustic resonator coupled between the input node and the output node in parallel to the pair of inductors;
an input shunt resonator coupled between the input node and a ground;
an output shunt resonator coupled between the output node and the ground; and
a middle node coupled to the ground; and
the acoustic network circuit comprises an acoustic ladder network coupled to the output node.

6. The loadline modulation power management circuit of claim 1, wherein:
the acoustic impedance inverter circuit comprises an acoustic impedance inverter comprising:
a pair of inductors coupled in series between an input node and an output node;
an input shunt resonator coupled between the input node and a ground;
an output shunt resonator coupled between the output node and the ground; and
a middle shunt resonator coupled between a middle node and the ground; and
the acoustic network circuit comprises a plurality of acoustic ladder networks each coupled to the output node.

7. The loadline modulation power management circuit of claim 1, wherein:
the acoustic impedance inverter circuit comprises an acoustic impedance inverter comprising:
a pair of inductors coupled in series between an input node and an output node;
a parallel acoustic resonator coupled between the input node and the output node in parallel to the pair of inductors;
an input shunt resonator coupled between the input node and a ground;
an output shunt resonator coupled between the output node and the ground; and
a middle node coupled to the ground; and
the acoustic network circuit comprises a plurality of acoustic ladder networks each coupled to the output node.

8. The loadline modulation power management circuit of claim 1, wherein:
the acoustic impedance inverter circuit comprises a plurality of acoustic impedance inverters each corresponding to a respective frequency band and comprising:
a pair of inductors coupled in series between an input node and an output node;
an input shunt resonator coupled between the input node and a ground;
an output shunt resonator coupled between the output node and the ground; and
a middle shunt resonator coupled between a middle node and the ground; and
the acoustic network circuit comprises a plurality of acoustic ladder networks each coupled to the output node of a respective one of the plurality of acoustic impedance inverters.

9. The loadline modulation power management circuit of claim 1, wherein:
the acoustic impedance inverter circuit comprises a plurality of acoustic impedance inverters each comprising:
a pair of inductors coupled in series between an input node and an output node;
a parallel acoustic resonator coupled between the input node and the output node in parallel to the pair of inductors;
an input shunt resonator coupled between the input node and a ground;
an output shunt resonator coupled between the output node and the ground; and
a middle node coupled to the ground; and
the acoustic network circuit comprises a plurality of acoustic ladder networks each coupled to the output node of a respective one of the plurality of acoustic impedance inverters.

10. A wireless device comprising a loadline modulation power management circuit, the loadline modulation power management circuit comprises:
a power amplifier circuit, comprising:
a differential amplifier always activated and configured to:
receive an envelope tracking (ET) voltage having a dynamic range defined by a minimum voltage level and a maximum voltage level; and
amplify a signal from a time-variant input power to a time-variant output power that is inversely related to a default loadline impedance based on the ET voltage; and
a single-ended amplifier activated when the time-variant output power is higher than or equal to a threshold level to reduce the default loadline impedance to thereby prevent the ET voltage from exceeding the maximum voltage level when the time-variant output power of the signal is higher than the threshold level; and
an acoustic filter circuit comprising an acoustic impedance inverter circuit and an acoustic network circuit and configured to pass the amplified signal in a transmit frequency and reject the signal outside the transmit frequency.

11. The wireless device of claim 10, wherein the single-ended amplifier is deactivated when the time-variant output power is lower than the threshold level.

12. The wireless device of claim 10, wherein the loadline modulation power management circuit further comprises:
a transformer circuit configured to couple the differential amplifier to an input of the acoustic impedance inverter circuit; and
an impedance transformation circuit coupled between the single-ended amplifier and an output of the acoustic impedance inverter circuit and configured to reduce the default loadline impedance when the single-ended amplifier is activated.

13. The wireless device of claim 10, wherein:
the acoustic impedance inverter circuit comprises an acoustic impedance inverter comprising:
a pair of inductors coupled in series between an input node and an output node;
an input shunt resonator coupled between the input node and a ground;
an output shunt resonator coupled between the output node and the ground; and
a middle shunt resonator coupled between a middle node and the ground; and
the acoustic network circuit comprises an acoustic ladder network coupled to the output node.

14. The wireless device of claim 10, wherein:
the acoustic impedance inverter circuit comprises an acoustic impedance inverter comprising:
a pair of inductors coupled in series between an input node and an output node;
a parallel acoustic resonator coupled between the input node and the output node in parallel to the pair of inductors;
an input shunt resonator coupled between the input node and a ground;
an output shunt resonator coupled between the output node and the ground; and
a middle node coupled to the ground; and
the acoustic network circuit comprises an acoustic ladder network coupled to the output node.

15. The wireless device of claim 10, wherein:
the acoustic impedance inverter circuit comprises an acoustic impedance inverter comprising:
a pair of inductors coupled in series between an input node and an output node;
an input shunt resonator coupled between the input node and a ground;
an output shunt resonator coupled between the output node and the ground; and
a middle shunt resonator coupled between a middle node and the ground; and
the acoustic network circuit comprises a plurality of acoustic ladder networks each coupled to the output node.

16. The wireless device of claim 10, wherein:
the acoustic impedance inverter circuit comprises an acoustic impedance inverter comprising:
a pair of inductors coupled in series between an input node and an output node;
a parallel acoustic resonator coupled between the input node and the output node in parallel to the pair of inductors;
an input shunt resonator coupled between the input node and a ground;
an output shunt resonator coupled between the output node and the ground; and
a middle node coupled to the ground; and
the acoustic network circuit comprises a plurality of acoustic ladder networks each coupled to the output node.

17. The wireless device of claim 10, wherein:
the acoustic impedance inverter circuit comprises a plurality of acoustic impedance inverters each corresponding to a respective frequency band and comprising:
a pair of inductors coupled in series between an input node and an output node;
an input shunt resonator coupled between the input node and a ground;
an output shunt resonator coupled between the output node and the ground; and
a middle shunt resonator coupled between a middle node and the ground; and
the acoustic network circuit comprises a plurality of acoustic ladder networks each coupled to the output node of a respective one of the plurality of acoustic impedance inverters.

18. The wireless device of claim 10, wherein:
the acoustic impedance inverter circuit comprises a plurality of acoustic impedance inverters each comprising:
a pair of inductors coupled in series between an input node and an output node;
a parallel acoustic resonator coupled between the input node and the output node in parallel to the pair of inductors;
an input shunt resonator coupled between the input node and a ground;
an output shunt resonator coupled between the output node and the ground; and
a middle node coupled to the ground; and
the acoustic network circuit comprises a plurality of acoustic ladder networks each coupled to the output node of a respective one of the plurality of acoustic impedance inverters.

19. The wireless device of claim 10, further comprising:
an ET integrated circuit (ETIC) configured to generate the ET voltage based on an ET target voltage; and
a transceiver circuit configured to generate the signal in the time-variant input power and the ET target voltage that tracks the time-variant input power.

20. A method for performing loadline modulation comprising:
receiving, by a differential amplifier that is always activated, an envelope tracking (ET) voltage having a dynamic range defined by a minimum voltage level and a maximum voltage level;
amplifying, by the differential amplifier, a signal from a time-variant input power to a time-variant output power that is inversely related to a default loadline impedance based on the ET voltage;
activating a single-ended amplifier when the time-variant output power is higher than or equal to a threshold level to reduce the default loadline impedance to thereby prevent the ET voltage from exceeding the maximum voltage level when the time-variant output power of the signal is higher than the threshold level; and
passing the amplified signal in a transmit frequency and rejecting the signal outside the transmit frequency.
